(19) United States
(12) Patent Application Publication
(10) Pub. No.: US 2014/0272341 A1
(43) Pub. Date: Sep. 18, 2014

(54) THERMAL TREATED SANDWICH STRUCTURE LAYER TO IMPROVE ADHESIVE STRENGTH

(71) Applicant: Applied Materials, Inc., Santa Clara, CA (US)

(72) Inventors: Ren-Guan DUAN, Fremont, CA (US); Juan Carlos ROCHA- ALVAREZ, San Carlos, CA (US)

(21) Appl. No.: 14/106,604

(22) Filed: Dec. 13, 2013

Related U.S. Application Data
(60) Provisional application No. 61/781,089, filed on Mar. 14, 2013.

(51) Int. Cl. H01L 21/02

(52) U.S. Cl. CPC H01L 21/02
USPC 428/212; 427/256; 427/448

(57) ABSTRACT

A method and apparatus for cleaning a process chamber are provided. In one embodiment, a process chamber is provided that includes a remote plasma source and a processing chamber. The processing chamber includes a substrate support assembly disposed in the bottom portion of the processing chamber, a gas distribution system configured to provide gas into the processing chamber above the substrate support assembly, a removable liner layer the chamber interior walls. An adhesion layer is disposed on the substrate support. A protective layer is disposed on the adhesion layer. Pluralities of intermediate layers are created between the substrate support layer and the adhesion layer, and the adhesion layer and the protective layer through a thermal treatment in a non-reactive environment.

### CROSS-REFERENCE TO RELATED APPLICATIONS

This application claims benefit of U.S. Provisional Application Ser. No. 61/781,089, filed Mar. 14, 2013 (Attorney Docket No. APPM/17559USL), of which is incorporated by reference in its entirety.

### BACKGROUND OF THE INVENTION

1. Field of the Invention

Embodiments herein relate to the field of semiconductor manufacturing processes and apparatus. More particularly, the embodiments relate to chambers and chamber components for deposition of thin film layers on substrates. The embodiments described herein provide a layer for protecting surfaces of processing chambers and components thereof during cleaning of the chamber, to reduce the incidence of defective, or contaminated, film layers on a substrate, and to extend the useful life of chamber components and to improve chamber performance, or the time period after which chamber components must be replaced or reconditioned.

2. Description of the Related Art

One known methodology for the deposition of thin film layers on a substrate used for semiconductor manufacturing comprises heating of the substrate and exposing the substrate to a chemical vapor mixture from which a thin film, such as a silicon oxide film, is deposited on the substrate. To enable a uniform temperature across a substrate in the deposition process, the substrate support, commonly called a suscepter, or a heater, may be manufactured of, or coated with, aluminum nitride (AlN). The substrate support heats, and supports, the substrate undergoing a thin film deposition process.

During the chemical vapor deposition (CVD) or plasma enhanced chemical vapor deposition (PECVD) process, as the substrates have the desired thin film layer formed thereon, a thin film layer of the deposition material also deposits on the chamber components, such as the shower head, liner and the heater, among other components. As the thin film layer deposited on these components accumulates or grows as substrates are consecutively processed in the chamber, process drift can result, and if portions of the deposited material become unattached from the chamber components, contamination and defects can be created on the substrates. Thus, the process chamber may require cleaning to remove undesirable deposition residues that may have formed in the chamber. To mitigate the defects and process drift, it is known in the art to use a remote plasma source (RPS), separate from the process chamber, to introduce a cleaning agent in a gas form to strip, or etch away, the deposition material accumulated on the chamber components.

The RPS provides cleaning plasma when silicon based film layers were deposited in the chamber, which may be formed from a fluorine-based cleaning gas, which is flowed into the deposition chamber via gas circulation hardware comprising a gas box, a gas manifold, and a gas distribution system installed in the process chamber. The cleaning agent aggressively removes the deposited film layers from the chamber surfaces. However, the cleaning agent also attacks the chamber surfaces, and particularly the AlN or AlN coated substrate support. As a result, the cleaning agent can creates free AlF3 particles which may contaminate later processed substrates. These particles are formed by erosion of the heater by the fluorine which, over time, is eroded to the point where replacement will be required.

It is known in the art to coat the AlN substrate support with a material which will not react as readily with the cleaning agent. One such layer is yttria. However, the adhesion of yttria to an AlN substrate support, or heater, has proven to be problematic, and, after sufficient thermal cycling of the heater, the yttria may flake off introducing new contamination into the process chamber and exposing the AlN substrate support again to the cleaning agent and the attendant erosion and failure thereof.

Therefore, there is a need for an improved apparatus and method for prolonging the longevity of the protective layer of the substrate support, and thus increase the time period or total duration of cleaning time over which the support or heater may be used before requiring refurbishment or replacement thereof.

### SUMMARY OF THE INVENTION

A method and apparatus for cleaning a process chamber are provided. In one embodiment, a process chamber is provided that includes a remote plasma source and a processing chamber. The processing chamber includes a substrate support assembly disposed in the bottom portion of the processing chamber, a gas distribution system configured to provide gas into the processing chamber above the substrate support assembly, and a removable liner layer disposed on the chamber interior walls. An exhaust system is provided to remove the by-products of reaction and un-reacted gases. A power supply is also provided to direct RF power to the chamber, commonly to the showerhead, to enable the striking and supporting of a plasma from the process gas in the chamber.

To protect a chamber component, for example, the substrate support, an adhesion layer is disposed on the substrate support, and a protective layer is disposed on the adhesion layer. The adhesion layer is selected to have a coefficient of thermal expansion intermediate of the substrate support material and the protective layer material. Further, a plurality of intermediate layers may be created between the substrate support layer and the adhesion layer, and the adhesion layer and the protective layer by thermal treatment of the substrate component, having the adhesion and protective layers formed thereon, by heating the component in a non-reactive environment. By interdiffusion of components of the adhesion layer and chamber component, and of the adhesion layer and protective layer, additional intermediate layers having different coefficients of thermal expansion may be formed to enhance the integrity of the protective layer during thermal cycling of the chamber component.

In another embodiment, a method is provided for creating a plurality of intermediate layers between a substrate support layer and an outermost protective layer. The method comprises depositing an adhesion layer on a substrate support, depositing a protective layer on the adhesion layer, and thermally treating the substrate support, adhesion layer and the protective layer in a non-reactive environment processing gas to allow interdiffusion to occur between the layers.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view showing a processing system having a cleaning system, according to one embodiment of the invention.

FIG. 2 is a schematic cross-sectional view illustrating the post-thermal treatment composition of the sandwich structure disposed on a substrate support, according to one embodiment of the invention.

FIG. 3 is a schematic cross-sectional view illustrating the pre-thermal treatment composition of a sandwich structure disposed on a substrate support, according to one embodiment of the invention.

FIG. 4 is a schematic cross-sectional view illustrating the AlOₓN_{y} layer in the thermally treated sandwich structure of FIG. 3, according to one embodiment of the invention.

FIG. 5 is a flow diagram illustrating a method for creating a plurality of intermediate layers to adhere a protective outer layer to a substrate support structure, according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein are useful for creating a strong adhesion between a layer comprised of an yttria based compound and an aluminum nitrate layer. The strong adhesion may be beneficial for use in a component or process which undergoes thermal cycling and where the layer of yttria may have a tendency to flake off.

Additional embodiments described herein are particularly useful in a substrate processing system that is operable to perform a plasma process (such as etch, CVD, PECVD and the like) on one or more substrates, and undergo plasma cleaning to remove residues formed during the deposition process while protecting the processing system from degradation due to the cleaning agent. One illustrated example of the substrate processing system comprises, without limitation, a remote plasma source, a processing chamber with a gas supply and exhaust pump and a substrate support configured with a thermally treated sandwich structure for protection of the substrate support during a cleaning process of the chamber in which it is located. To remove deposition residues from the interior of the process chamber, and from the substrate support, a remote plasma source supplies, into the interior of the process chamber from the top or side of the process chamber, a cleaning agent in a radicalized or plasma state. A protective outer layer of the thermally treated sandwich structure provides protection for the substrate support from the aggressive cleaning agent while middle layers of the thermally treated sandwich structure adhere the outer protective layer to the substrate support during thermal cycling of the substrate support. As a result, the integrity, and lifetime, of the protective outer layer of the thermally treated sandwich structure, and the underlying substrate support, is enhanced and extended.

FIG. 1 is a schematic cross-sectional view of a plasma enhanced chemical vapor deposition system 100 according to an embodiment of the invention. The plasma enhanced chemical vapor deposition system 100 generally includes a chemical vapor deposition chamber 103 coupled to a precursor supply 152. The chemical vapor deposition chamber 103 has sidewalls 106, a bottom 108, and a lid assembly 110 that define a processing volume 112 inside the chamber. The processing volume 112 is accessed through a port (not shown) in the sidewalls 106 that facilitates movement of a substrate 140 into and out of the chemical vapor deposition chamber 103. The chamber, sidewalls 106 and bottom 108, are fabricated from aluminum, stainless steel, or other materials compatible with processing. The sidewalls 106 are provided with a removable liner 170 for ease of cleaning. The sidewalls 106 support a lid assembly 110 that contains a pumping plenum 114 that couples the processing volume 112 to an exhaust system that includes various pumping components (not shown). The sidewalls 106, bottom 108, and lid assembly 110 define the chamber body 102.

A gas inlet conduit or pipe 144 extends into an entry port or inlet 180 in a central lid region of the chamber body 102 and is connected to sources of various gases. A precursor supply 152 contains the precursors that are used during deposition. The precursors may be gases or liquids, and if a liquid, the liquid is vaporized or otherwise produced in a gas like form therefrom for deposition of a film layer on a substrate. The particular precursors that are used depend upon the materials that are to be deposited onto the substrate. The process gases flow through the inlet pipe 144 into the inlet 180 and then into the chemical vapor deposition chamber 103. An electronically operated valve and flow control mechanism 154 controls the flow of gases from the gas supply into the inlet 180.

A second gas supply system 160 is also connected to the chamber through the inlet pipe 144. The second gas supply system 160 supplies gas that is used to clean, e.g., to remove deposited material, from the inside of the chamber after one or more chemical vapor deposition processes have been performed in the chamber. In some situations, the first and second gas supplies can be combined. In other situations the second gas supply system 160 may be connected through an inlet pipe 143 in the side of the processing volume 112.

The second gas supply system 160 includes a source 164 of a cleaning gas (or liquid), such as nitrogen trifluoride or sulfur hexafluoride, a remote plasma source 166 which is located outside and at a distance from the chemical vapor deposition chamber, an electronically operated valve and flow control mechanism 162, and a conduit 177 connecting the remote plasma source to the chemical vapor deposition chamber 103. Such a configuration allows interior surfaces of the chamber to be cleaned using a remote plasma source.

The second gas supply system 160 also includes one or more sources 172 of one or more additional gases (or liquids) such as a carrier gas. The additional gases are connected to the remote plasma source 166 through another valve and flow control mechanism 173. The carrier gas aids in the transport of the reactive species generated in the remote plasma source to the deposition chamber and can be any nonreactive gas that is compatible with the particular cleaning process with which it is being used. For example, the carrier gas may be argon, nitrogen, or helium. The carrier gas also may assist in the cleaning process or help initiate and/or stabilize the plasma in the chemical vapor deposition chamber.

The valve and flow control mechanism 162 delivers gas from the source 164 into the remote plasma source 166 at a user-selected flow rate. The remote plasma source 166 may be an RF plasma source, such as an inductively coupled remote plasma source. The remote plasma source 166 activates the gas or liquid from the source 164 to form reactive species which are then flowed through the conduit 177 and the inlet pipe 144 into the deposition chamber through the inlet 180. The inlet 180 is, therefore, used to deliver the reactive species into the interior region of the chemical vapor deposition chamber 103 that includes the processing volume 112.

The lid assembly 110 provides an upper boundary to the processing volume 112. The lid assembly 110 includes a central lid region 105 in which the inlet 180 is defined. The lid assembly 110 can be removed or opened to service the chemical vapor deposition chamber 103. The lid assembly 110 includes a pumping plenum 114 formed therein coupled to an external pumping system (not shown). The pumping plenum 114 is utilized to channel gases and processing by-products uniformly from the processing volume 112 and out of the chemical vapor deposition chamber 103.

The gas distribution assembly 118 is coupled to an interior side 120 of the lid assembly 110. The gas distribution assembly 118 includes a perforated area 116 in a gas distribution plate (Shower head) 158 through which gases, including reactive species generated by the remote plasma source and processing gases for chemical vapor deposition, are delivered to the processing volume 112. The perforated area 116 of the gas distribution plate 158 is configured to provide uniform distribution of gases passing through the gas distribution assembly 118 into the process volume 112.

The gas distribution plate 158 is fabricated from stainless steel, aluminum (Al), anodized aluminum, nickel (Ni) or another RF conductive material. The gas distribution plate 158 is configured with a thickness that maintains sufficient flatness and uniformity so as to not adversely affect substrate processing.

In addition to inlet 180, the chamber body 102 may include an alternative or second inlet 182 for providing reactive species from a remote plasma source. The second inlet 182 is configured to provide reactive species from the remote plasma source into the processing volume 112 of the chemical vapor deposition chamber 103 while bypassing the gas distribution assembly 118. In other words, the reactive species provided by the second inlet 182 do not pass through the perforated gas distribution plate 158 of the gas distribution assembly 118. The second inlet may be located in a sidewall 106 of the chamber body 102 below the gas distribution assembly 118, such as between the gas distribution plate 158 and the substrate support 124. A gas inlet pipe 143 from the remote plasma source to the second inlet 182 delivers reactive species from the remote plasma source to the processing volume 112 of the chemical vapor deposition chamber 103 through the second inlet 182.

A temperature controlled substrate support assembly 138, having a protective layer 211, is centrally disposed within the chemical vapor deposition chamber 103. The support assembly 138 supports a substrate 140 during processing. In one embodiment, the substrate support assembly 138 comprises a substrate support 124 having an aluminum nitride body that encapsulates at least one heater 132 (heating element) therein. The heater 132, such as a resistive element disposed in the support assembly 138, is coupled to an optional power source 174 and controllably heats the support assembly 138 and the substrate 140 positioned thereon to a predetermined temperature. Generally, the support assembly 138 has a substrate support 124 comprising a lower side 126 and an upper side 134. The upper side 134 supports the substrate 140. The lower side 126 has a stem 142 coupled thereto. The stem 142 couples the support assembly 138 to a lift system (not shown) that moves the support assembly 138 between an elevated processing position (as shown) and a lowered position that facilitates substrate transfer to and from the chemical vapor deposition chamber 103 and the heater 132. The stem 142 additionally provides a conduit for electrical and thermocouple leads between the support assembly 138 and the exterior of the chamber.

The support assembly 138 generally is grounded such that RF power supplied by a power source 122 to the gas distribution assembly 118 positioned between the lid assembly 110 and substrate support assembly 138 (or other electrode positioned within or near the lid assembly of the chamber) may excite gases present in the processing volume 112 between the support assembly 138 and the gas distribution assembly 118. The support assembly 138 may include an electrostatic chuck or other means to hold the substrate 140 during processing. The support assembly 138 has a plurality of holes 128 disposed there through that accept a plurality of lift pins 150 that are used to place, and remove, a substrate on and off of the support.

FIG. 2 is a schematic cross-sectional view illustrating the post-thermal treatment composition of the sandwich structure 200 disposed on a substrate support, according to one embodiment of the invention. The sandwich structure 200 includes a substrate support structure 201 comprising aluminum nitride (AlN) heater 230, having an Al₂O₃ layer 220, and a Y₂₋ₓZrₓO₃—Y₄Al₂O₉ layer 210 or Y₂O₃ layer formed thereon in that order. The Y₂₋ₓZrₓO₃—Y₄Al₂O₉ layer 210 or Y₂O₃ layer forms the protective layer 211 which protects the substrate support surfaces from the CVD chemistry and the cleaning chemistries. In the embodiment shown, the sandwich structure 200 is first formed as two different layers, an Al₂O₃ layer 220, and a or Y₂O₃ layer or Y₂₋ₓZrₓO₃—Y₄Al₂O₉ layer 210, which is then heat treated to form additional Y₃Al₅O₁₂ layer 215 and AlOₓN_{y} layer 225. In order to quantitatively consider AlOₓN_{y} layer 225, it can be expressed as Al₁₊ₓO₃ₓN₁₋ₓ (x=0-1). The composition of the Al₁₊ₓO₃ₓN₁₋ₓ layer 225 is variable wherein the x value may range from 0 to 1 along direction AlN heater 230 to Al₂O₃ layer 220.

The substrate support structure 201 is the same temperature controlled substrate support assembly 138 as shown in the chemical vapor deposition chamber 103 of FIG. 1. To facilitate efficient heat distribution across the substrate support structure 201, the substrate support structure 201 may be comprised of a heat conductive material such as Aluminum Nitride (AlN). However, the layer of heat conductive material may be comprised of any number of materials displaying outstanding heat conductivity.

During each deposition cycle, i.e., formation of a film layer on a substrate, the film also forms on areas of a chamber exposed to the deposition gasses, including on the sidewall of the heater 230. In order to maintain consistency in the manufacturing process, the built-up film layer material is periodically cleaned from the chamber components in-situ. However, the cleaning agents aggressively attack the exposed surfaces of the heater 230. One mitigation method is to include a dummy substrate, i.e. shutter disk, to shield the area covered by a substrate during the chemical vapor deposition process. However, the shutter disk does not cover the side wall of the heater 230 which is exposed to the aggressive cleaning materials, such as Fluorine gas, which readily react with any exposed aluminum nitride and erode the surface thereof. Therefore, the side wall, and other areas of the heater, 230 are coated with a protective layer 211.

In an embodiment, the protective layer 211 is formed of plasma sprayed yttria oxide and yttria based materials. Two examples of these materials are:

(1) pure Y₂O₃ and

(2) Y₂O₃—ZrO₂—Al₂O₃ material.

For the Y₂O₃—ZrO₂—Al₂O₃ material, the starting raw powder is Y₂O₃, ZrO₂ and Al₂O₃ and the final sintered phase is Y₄Al₂O₉ (YAM) and Y₂₋ₓZrₓO₃(Y₂O₃—ZrO₂ solid solution) thus producing an Y₂₋ₓZrₓO₃—Y₄Al₂O₉ layer 210. Pure Y₂O₃ and Y₂O₃ based materials provide much better protection against an attack by fluorine and plasma as compared to aluminum based materials, such as AlN. The Y₂₋ₓZrₓO₃—Y₄Al₂O₉ layer 210, or Y₂O₃ layer, significantly reduces, or eliminates, AlFₓ formation during the cleaning process, and thus increases the heater lifetime. However the thermal expansion coefficient for Y₂₋ₓZrₓO₃—Y₄Al₂O₉ layer 210 is 8.5×10⁻⁶/k and the Y₂O₃ layer is 7.9×10⁻⁶/k. Comparatively, the thermal expansion coefficient for AlN heater 230 is 5.6×10⁻⁶/k. The differences in the thermal expansion coefficient causes the two materials to separate over time, i.e., delaminate, as the substrate support structure 201 thermally cycles.

To ameliorate the effect of the difference in coefficient of thermal expansion between the support and the protective yttria layer, an Al₂O₃ layer 220 is first applied as an intermediate layer on the AlN heater 230 and the Y₂₋ₓZrₓO₃—Y₄Al₂O₉ layer 210, or Y₂O₃ layer, is formed there over. One such sandwich structure layer may be formed (one alumina layer between the AlN surface of the heater and the yttria based layer). However, the thermal expansion coefficient for Al₂O₃ layer 220 is 8.1×10⁻⁶/k. Thus, the Al₂O₃ layer 220 experiences expansion that will also create adhesion problems with the underlying AlN heater 230.

However, the inventors herein has discovered that by annealing the sandwich structure at high temperature in a non-reactive environment, the materials of the sandwich structure interdiffuse, thereby forming inter-metallic or inter-element compounds which have differing coefficients of thermal expansion which enhance the integrity and longevity of the protective layer which would otherwise delaminate from the heater 230. Thus, a gradual change in the thermal coefficient of expansion between the heater 230 and the Y₂₋ₓZrₓO₃—Y₄Al₂O₉ layer 210, or Y₂O₃ layer, may be incorporated into the sandwich structure 200.

As a result of thermally treating the heater 230 and sandwich structure 200 in a non-reactive environment, interdiffused material layers are formed. An AlOₓN_{y} layer 225 is formed between AlN surface of the heater 230 and the Al₂O₃ layer 220, and an Y₃Al₅O₁₂ (YAG) layer 215 is formed between the yttria based Y₂₋ₓZrₓO₃—Y₄Al₂O₉ layer 210, or Y₂O₃ layer, and the Al₂O₃ layer 220.

In the resulting sandwich structure, the thermal expansion coefficient increases gradually through the AlOₓN_{y} material to the outer yttria oxide layer. The thermal expansion coefficient for AlOₓN_{y} layer 225 ranges from 5.6 to 8.1×10⁻⁶/k. And the thermal expansion coefficient for the Y₃Al₅O₁₂ layer 215 is 8.2×10⁻⁶/k. Thus the sandwich structure 200 forms a functionally graded material, significantly increasing the adhesive strength of the sandwich structure as shown in table 1 below:

TABLE 1

| | Thermal Expansion Coefficient (×10⁻⁶/K) |
|---|---|
| Y2−xZrxO3—Y4Al2O9 | 8.5 |
| Y3Al5O12 (YAG) | 8.2 |
| Al2O3 | 8.1 |
| AlOxNy | 5.6-8.1 |
| AlN | 5.6 |

In one embodiment, the sandwich structure 200 is thermally treated at 1750 C in a nitrogen atmosphere causing the AlOₓN_{y} layer 225 to form between the AlN heater 230 and the Al₂O₃ layer 220, and the Y₃Al₅O₁₂ layer 215 to form between the Al₂O₃ layer 220 and the top or outer protective Y₂₋ₓZrₓO₃—Y₄Al₂O₉ layer 210, or Y₂O₃ layer.

FIG. 3 is a schematic cross-sectional view illustrating the AlOₓN_{y} layer 225 in the thermally treated sandwich structure 200 of FIG. 2, according to one embodiment of the invention. In order to quantitatively consider AlOxNy, it can be expressed as Al₁₊ₓO₃ₓN₁₋ₓ (x=0-1). The Al₁₊ₓO₃ₓN₁₋ₓ layer 225 includes a layer where (x close to 1) 310, a layer where (x=0.25) 320, and a layer where (x close to 0) 330. Layer (x close to 1) 310 is the outermost surface 340 and layer (x close to 0) 330 is the innermost surface 350. Although the figure depicts three layers, the layers are a gradually transformed composition and the ranges depict the percentage of oxygen and nitrogen respective to each other in the AlOₓN_{y} layer 225. That is for layer (x close to 1) 310 includes the set of all compounds for Al₁₊ₓO₃ₓN₁₋ₓ where the value of x is 0.85-1, layer (x=0.25) 320 includes the set of all compounds for Al₁₊ₓO₃ₓN₁₋ₓ where the value of x is equal to 0.15-0.85, and layer (x close to 0) 320 includes the set of all compounds for Al₁₊ₓO₃ₓN₁₋ₓ where the value of x is 0-0.15. For Example, Al_{1.95}O_{2.85}N_{0.05} would be a member of the set of Al₁₊ₓO₃ₓN₁₋ₓ belonging to the layer (x close to 1) 310. Thus, the layers form a continuum of changing ratios of x from 0 to 1.

Referring back to table 1, the thermal expansion coefficient for Al₁₊ₓO₃ₓN₁₋ₓ layer 225 is shown to range between 5.6×10⁻⁶/k and 8.1×10⁻⁶/k. The thermal expansion coefficient for the Al₁₊ₓO₃ₓN₁₋ₓ layer 225 is near 5.6×10⁻⁶/k as x approaches 0 and 8.1×10⁻⁶/k as x approaches 1. Each increment as x goes from 0 to 1 in the Al₁₊ₓO₃ₓN₁₋ₓ layer 225 brings about an incremental change in the thermal expansion coefficient. In other words, at the top or outermost surface 340 of layer (x close to 1) 310, the thermal expansion coefficient is near 8.1×10⁻⁶/k and the thermal expansion coefficient incrementally decrements until reaching the bottom, or innermost surface, of layer (x close to 0) 330 where the thermal expansion coefficient is near 5.6×10⁻⁶/k. The sandwich structure 200 has a gradually transformed thermal expansion coefficient, in the ranges shown in Table 1, and thus significantly increases the adhesive strength for the outer protective Y_{2-z}ZrₓO₃—Y₄Al₂O₉ layer 210, or Y₂O₃ layer. The resulting sandwich layer is one functionally graded material, and shows better adhesion performance than a single layer.

FIG. 4 is a schematic cross-sectional view illustrating the pre-thermal treatment structure of a sandwich structure 400 disposed on a substrate support useful for the creation of sandwich structure 200 depicted in FIG. 2, according to one embodiment of the invention. FIG. 4 incorporates the numbering convention from FIG. 2 for the same materials and structures.

Prior to thermal treatment, the sandwich structure contains three distinct layers. The sandwich structure 400 includes a substrate support structure 201 comprising aluminum nitride (AlN), having an Al₂O₃ layer 220, and an Y₂₋ₓZrₓO₃—Y₄Al₂O₉ layer 210, or Y₂O₃ layer, formed thereon in that order. Thermal treatment is performed on sandwich structure 400 of FIG. 4 to create the sandwich structure 200 of FIG. 2.

The thermal treatment of sandwich structure 400 may be performed in a non-reactive environment, such as in an argon or nitrogen environment. Such an environment may exist in an annealing oven, a kiln, furnace or other device. A useful temperature range for annealing may be set between 1000-1800 C with the sandwich structure 400 exposed to this temperature for a period of 0.5-24 hrs. to form sandwich structure 200.

FIG. 5 is a flowchart illustrating a method for creating a plurality of intermediate layers to adhere a protective outer layer to a substrate support structure, according to one embodiment of the invention. However, the method may be useful for adhering similar compounds to any surface which undergo thermal cycles, even those outside of chemical vapor deposition processes.

In block 510, an adhesive layer is applied onto a top surface and a side surface of the substrate support structure wherein the substrate support structure is of an aluminum compound. In one embodiment, the substrate support structure is AlN and the adhesive is Al₂O₃. The application of the adhesive may be performed in a number of methods for manufacture. In a particular embodiment Al₂O₃ is applied with a plasma spray to the outer surface of the AlN substrate support structure.

In block 520, a protective layer is applied onto the adhesive layer. In one embodiment the protective layer is a yttria compound such as Y₂O₃—ZrO₂—Al₂O₃. The protective layer may be applied in a number of ways. And in the same embodiment, a protective layer comprised of Y₂O₃—ZrO₂—Al₂O₃ is applied with a plasma spray to the outer surface of the Al₂O₃ adhesive disposed on the substrate support structure. The layer of the protective layer is applied to exposed surfaces for which reactive agents or other destructive elements which may come into contact with the surface requiring protection.

In block 530, the substrate support structure is treated in a thermal process. A thermal treatment is performed on layers applied to the substrate support structure. The thermal treatment is performed in a nitrogen non-reactive environment. The thermal treatment may be performed in a kiln, furnace or other device. In one embodiment, the substrate support structure is heated in a nitrogen filled furnace to a temperature between 1000-1800 C for a period of 0.5-24 hrs. The thermal treatment causes the AlN to interdiffuse with the Al₂O₃ and additionally the Al₂O₃ to interdiffuse with the Y₂O₃—ZrO₂—Al₂O₃.

In block 540, the layers comprising the substrate support structure interdiffuse resulting in the creation of an AlOₓN_{y} layer 225 formed between the AlN and the Al₂O₃ layer, and an Y₃Al₅O₁₂ (YAG) layer formed between the Y₂₋ₓZrₓO₃—Y₄Al₂O₉ layer and the Al₂O₃ layer. A gradient in the thermal coefficient of expansion is formed from a top surface of the substrate support structure to the protective layer. In one embodiment, the formed layers now contain layers of AlOₓN_{y}, and layer of Y₃Al₅O₁₂.

Although the embodiments herein are described with respect to an AlN heater used in a chemical vapor deposition chamber, the thermally treated sandwich structure for improving the adhesive strength of the protective layer of the AlN heater can be employed on other chamber components, such as those components used in physical vapor deposition, etch, or other plasma process where adhesion of a protective layer to an aluminum nitride component is important. While the foregoing is directed to certain embodiments of the present invention, other and further embodiments of the invention may be devised without departing from the basic scope thereof, and the scope thereof is determined by the claims that follow.

What is claimed is:

1. A protective coating; comprising:
a first material layer having a surface to be protected;
a second material layer overlying the first material layer; and
a third material layer, overlying the second material layer; wherein an interdiffused material formed of at least a portion of the second material layer and a portion of one of the first and the third material layers is provided, and, the interdiffused material has a thermal property different than the first, second and third material layers.

2. The protective coating of claim 1, wherein the interdiffused material comprises portions of the first and the second material layers, and the thermal property is a coefficient of thermal expansion.

3. The protective coating of claim 2, wherein the coefficient of thermal expansion increases in the interdiffused material in a direction of the third material layer.

4. The protective coating of claim 1, wherein the third material layer is an yttria oxide or yttria oxide based material.

5. The protective coating of claim 4, wherein the first material layer comprises AlN.

6. The protective coating of claim 2 wherein the second material layer comprises Al₂O₃.

7. The protective coating of claim 1, wherein a coefficient of thermal expansion for the interdiffused material is the same as the first material layer where the interdiffused material and the first material layer contact one another.

8. The protective coating of claim 6, further including a second interdiffused material formed of, and located between the third layer and the second material layer, and the coefficient of thermal expansion of the second interdiffused material is intermediate that of the second and the third material layers.

9. The protective coating of claim 1, wherein the protective coating is disposed on a substrate support.

10. A method for protecting a surface of a chamber component, comprising:
applying an adhesive layer onto the surface of the chamber component to be protected;
applying a protective layer onto the adhesive layer;
thermally treating the chamber component; and thereby
forming a graded layer having a graded increase in a coefficient of thermal expansion increasing from the surface thereof closest to the chamber component and highest in a portion thereof closest to the protective layer.

11. The method of claim 10, wherein the protective layer is applied with a plasma spray device.

12. The method of claim 11, wherein the protective layer is a yttria based compound.

13. The method of claim 10, wherein the chamber component is an aluminum nitrate substrate support structure with a heating element.

14. The method of claim 13 wherein the adhesive layer is A₂O₃.

15. The method of claim 14, wherein thermally treating the chamber component to a thermal process comprises:
heating the chamber component in an oven to a temperature over a period of time which causes a material of the chamber component, the adhesive layer and the protective layer to interdiffuse.

16. A protective coating for a substrate support structure comprising:
a first layer;
an adhesive layer disposed on the first layer;
a protective layer disposed on the adhesive layer;
a first interdiffused layer formed of at least a portion of the adhesive layer and a portion of the first layer wherein the first interdiffused layer has a thermal property gradually changing from the first layer to the adhesive layer; and
a second interdiffused layer formed of at least a portion of the adhesive layer and a portion of the protective layer wherein the second interdiffused layer has a different thermal property than the adhesive layer and the protective layer.

17. The protective coating for a substrate support structure of claim 16 wherein the protective layer is an yttria based compound.

18. The protective coating for a substrate support structure of claim 16 wherein the first layer is an aluminum nitrate compound.

19. The protective coating for a substrate support structure of claim 16 wherein the adhesive layer is A₂O₃.

20. The protective coating for a substrate support structure of claim 16 wherein the thermal property is a coefficient of thermal expansion.
